(19) United States
(12) Patent Application Publication
(10) Pub. No.: US 2003/0025171 A1
(43) Pub. Date: Feb. 6, 2003

(54) Multiple epitaxial region substrate and technique for making the same

(76) Inventors: Jonathan Charles Geske, Ventura, CA (US); Vijaysekhar Jayaraman, Goleta, CA (US)

Correspondence Address: MORGAN & FINNEGAN, L.L.P., 345 Park Avenue, New York, NY, 10154, US

(21) Appl. No.: 10/207,878

(22) Filed: Jul. 31, 2002

Related U.S. Application Data
(60) Provisional application No. 60/308,604, filed on Jul. 31, 2001.

(51) Int. Cl. H01L 21/30

(52) U.S. Cl. 257/455

(57) ABSTRACT

A method of forming a semiconductor substrate having a plurality of epitaxial regions disposed at different lateral locations, includes assembling a plurality of epitaxial layers vertically adjacent to each other on a host substrate to form an epitaxial structure; etching a surface of the epitaxial structure to reveal epitaxial regions of the epitaxial layers at different lateral locations on the host substrate; and wafer bonding the etched surface of the epitaxial structure to a transfer substrate.

### BACKGROUND

1. Technical Field

The present invention is generally related to a multiple epitaxial region substrate and technique for making the same.

2. Art Background

A classic problem in the field of hetero-junction opto-electronic devices is realizing substantial lateral or transverse variation (in the plane of the wafer) in the epitaxial structure grown on a wafer. Substantial lateral variation refers to lateral variation that cannot be achieved through post-growth processing alone or by lateral layer thickness variation during growth. Achieving such variation enables the integration of dissimilar devices or dissimilar device regions on the same substrate. Examples of this include integration of a laser and detector, laser and modulator, detector and amplifier, or integration of multiple lasers/modulators with different quantum well designs laterally adjacent on the same substrate.

Previous approaches to this problem in the literature have included epitaxial regrowth and aligned wafer bonding. See e.g., Elias Towe, ed. “Heterogeneous Opto-Electronic Integration,” SPIE Press, 2000, Bellingham, Wash., Chapter 1. FIG. 1 illustrates epitaxial regrowth, where one region is grown and etched away, and a second region is selectively regrown in the etched region. FIG. 2 illustrates the wafer-bonded approach, where stripes or islands from a host substrate are bonded to specific locations on a final substrate.

With either the epitaxial regrowth or aligned wafer bonding approach, the number of bond/regrowth steps increases as the number of epitaxial regions. Since each bonding and regrowth step results in some yield loss, and in exposure of the wafer to potentially damaging high temperature processing, it is difficult in practice to achieve more than about two epitaxial regions with these techniques.

### SUMMARY

In one embodiment, there is provided a method of forming a semiconductor substrate having a plurality of epitaxial regions disposed at different lateral locations. The method includes assembling a plurality of epitaxial layers vertically adjacent to each other on a host substrate to form an epitaxial structure; etching a surface of the epitaxial structure to reveal epitaxial regions of the epitaxial layers at different lateral locations on the host substrate; and wafer bonding the etched surface of the epitaxial structure to a transfer substrate.

A backside of the host or transfer substrate can be etched or materials can be deposited on the host or transfer substrate to reduce lateral thickness variations in the bonded structure, prior to wafer bonding. For example, a backside of the host substrate, opposite the epitaxial structure, can be etched to reduce lateral thickness variation of the host substrate plus the epitaxial layers, prior to wafer bonding. A backside of the transfer substrate, opposite a bonding side, can be etched to reduce the lateral thickness variation of the transfer substrate plus the epitaxial layers plus the host substrate, prior to wafer bonding. Material can be deposited on a backside of the host substrate, opposite the epitaxial layers, to reduce lateral thickness variation of the host substrate plus the deposited material plus the epitaxial layers, prior to wafer bonding. Material can be deposited on a backside of the transfer substrate to be bonded to reduce the lateral thickness variation of the transfer substrate plus the host substrate plus the deposited material plus the epitaxial layers, prior to wafer bonding.

A surface of the transfer substrate can be etched to form a bonding surface having a complementary shape to the etched surface of the epitaxial structure on the host substrate; and the host substrate and the transfer substrate, can be aligned prior to wafer bonding, to reduce the lateral thickness variation of the host substrate plus the epitaxial layers plus the transfer substrate.

As part of the wafer bonding, pressure can be applied with at least one pressure block having a surface for pressure application which has a shape that substantially reduces the lateral thickness variation of the pressure block plus the host substrate plus the epitaxial layers plus the transfer substrate.

The host substrate and excess epitaxial layers of the bonded epitaxial structure can be removed to form a final substrate having a plurality of remaining epitaxial regions arranged at different lateral locations thereon and bonded thereto across a single bonded interface. Deformation regions may also be formed between revealed epitaxial regions of the epitaxial structure bonded to the transfer substrate, and removed accordingly.

The bond can be a direct semiconductor-to-semiconductor bond, or may involve intermediate layer(s), such as metal, epoxy, or dielectric films or stack (e.g., dielectric thin films or stack). The transfer substrate may also take various forms, as desired, such as a semiconductor, a conductor (e.g., metal), an insulator (e.g., dielectric material such as patterned dielectric film(s) or stack) or combination thereof.

Notches at cleavage points can be provided on the etched epitaxial structure to promote cleavage along planes intersecting the notches when the epitaxial structure is bonded to the transfer substrate. The notches can be provided on the epitaxial structure at positions between revealed epitaxial regions. The notches may be formed in various ways, for example, by scratching or other well-known techniques.

At least one of the remaining epitaxial regions of the final substrate can be processed to form one of an optical, micromechanical and electronic device and another of the remaining epitaxial regions to form an electrical drive circuit for one of an optical, micromechanical and electronic device. The optical device can be a laser or a photo-detector. Two different epitaxial regions of the final substrate can be processed to form two different devices therefrom.

In another embodiment, there is provided a method of forming a semiconductor substrate having a plurality of epitaxial regions disposed at different lateral locations. The method includes forming an epitaxial structure on a host substrate, the epitaxial structure having a surface in which at least two different epitaxial regions of different epitaxial layers are exposed and arranged at different lateral and vertical locations on the host substrate; and wafer bonding the surface of the epitaxial structure to a transfer substrate; removing the host substrate and excess epitaxial layers to form a substrate having at least two different epitaxial regions thereon at different lateral locations and connected across a single wafer bonded interface.

In a further embodiment, a semiconductor structure includes a substrate with at least two epitaxial regions laterally disposed thereon. Each of the epitaxial regions is non-convertible to any of the other epitaxial regions through post-growth processing alone, and formed from different epitaxial layers. A single common wafer bonded interface is provided between each of the epitaxial regions and the substrate.

Each epitaxial region can form a laser gain medium with each gain medium having a different peak gain wavelength. A semiconductor laser can be processed on each epitaxial region with each semiconductor laser emitting at a different wavelength. Each semiconductor laser can have the same wavelength offset between its lasing wavelength and its corresponding gain peak wavelength.

Each laser can be a single-longitudinal-mode in-plane laser, a vertical cavity surface emitting laser (VCSEL), a tunable laser, or other type of laser. Each VCSEL can operate in the range of approximately 1200 nanometer (nm) to approximately 1650 nm, and/or can include a vertically integrated VCSEL optical pump. Each tunable laser can include at least one sampled grating, and may be a MEMs tunable VCSEL.

Each epitaxial region can include an absorption region for an electro-absorption modulator. Each absorption region can have a substantially different absorption band-edge. The electro-absorption modulator can processed on each epitaxial region.

Generally, the epitaxial regions may be formed with different properties and processed into various components, as desired. A few examples may include the following:

(1) One of the epitaxial regions can be optically active and another of the regions can be optically passive.

(2) One of the regions can be processed into a detector for detecting optical radiation, and another can be processed into an amplifier circuit for amplifying the photocurrent generated by the detector.

(3) One of the regions can be processed into a laser, and another region can processed into a circuit for applying electrical drive to the laser.

(4) One of the regions can be processed into a laser and another into a modulator that modulates at least one of an amplitude and phase of light emitted by the laser.

(5) One of the regions can be processed into a laser, and another of the regions can be processed into a detector for detecting optical radiation.

In yet another embodiment, a wavelength-division multiplexed fiber optic transmitter includes a wavelength-division multiplexed array of lasers and an electro-absorption modulator array coupled to the laser array. The modulator array includes a semiconductor structure having a substrate with at least two epitaxial regions laterally disposed thereon. Each of the epitaxial regions is non-convertible to any of the other epitaxial regions through post-growth processing alone, and formed from different epitaxial layers. A single common wafer bonded interface is provided between each of the epitaxial regions and the substrate. Each epitaxial region includes an absorption region for an electro-absorption modulator, and an electro-absorption modulator is processed on each epitaxial region. Each modulator in the array can have a band edge substantially optimized to provide low-chirp modulation for the wavelength of light coupled thereto.

In a further embodiment, a wavelength-division multiplexed fiber optic transmitter includes an electro-absorption modulator array, coupled to a wavelength-division multiplexed array of lasers. The laser array has a semiconductor structure including (1) a substrate, at least two epitaxial regions laterally disposed on the substrate, each of the epitaxial regions non-convertible to any of the other epitaxial regions through post-growth processing alone, and formed from different epitaxial layers, and (2) a single common wafer bonded interface between each of the epitaxial regions and the substrate. Each epitaxial region has a gain region for a laser-and a laser is processed on each epitaxial region.

Each laser in the array can have the same wavelength offset between its lasing wavelength and its corresponding gain peak wavelength.

Other and further embodiments will become apparent during the course of the following description and by reference to the attached drawings.

### BRIEF DESCRIPTION OF THE DRAWINGS

FIG. 1 illustrates epitaxial regrowth in which one region is grown and etched away, and a second region is selectively re-grown in the etched region;

FIG. 2 illustrates a wafer-bonded approach in which stripes or islands from a host substrate are bonded to specific locations on a final substrate;

FIGS. 3A through 3D illustrate an exemplary process of forming multiple epitaxial regions on a substrate in accordance with one advantageous embodiment;

FIG. 4 illustrates an exemplary process of performing an aligned wafer bond to a substrate with a complementary etch pattern;

FIGS. 5A through 5D illustrate an exemplary process of performing complementary backside etching or deposition to facilitate non-planar bonding;

FIG. 6 illustrates an exemplary process of employing a non-planar pressure block during wafer bonding;

FIGS. 7A and 7B illustrate an exemplary process of causing wafers to cleave along, or near, step edges during bonding;

FIGS. 8A and 8B illustrate an example of integrating different quantum well emission peaks on one substrate;

FIG. 9 illustrates a wavelength-division-multiplexed (WDM) array of optically pumped vertical cavity surface emitting lasers (VCSELs) formed on a single substrate;

FIGS. 10A and 10B illustrate an example of integrating drive electronics with semiconductor lasers or photo-detectors on one substrate;

FIG. 11 illustrates a schematic of an example structure with four regions epitaxially grown on a substrate;

FIG. 12 illustrates cross-section schematics showing: (a) the epitaxial film side and backside of the as-grown wafer etched with a step profile, (b) the epitaxial layers bonded to the transfer substrate with the growth substrate removed (α and β denote observations points for FIG. 15), (c) the original vertically grown epitaxial regions now laterally integrated on the transfer substrate after non-planar bonding, growth substrate removal, and the etch-back of the excess epitaxial layers;

FIG. 13 illustrates an optical photograph of a surface of a transfer substrate after substrate removal and etch-back of excess epitaxial layers in which the etched deformation accommodation regions separate the four well-bonded different epitaxial regions;

FIG. 14 illustrates photoluminescence (PL) from the four different bonded epitaxial regions of FIGS. 11 and 12 after the non-planar wafer bonding process; and

FIG. 15 illustrates a cross-section scanning electron micrographs of the bonded interface taken at the two observation points α and β schematically depicted in FIG. 12(b) in which the photos were taken prior to the InP substrate removal.

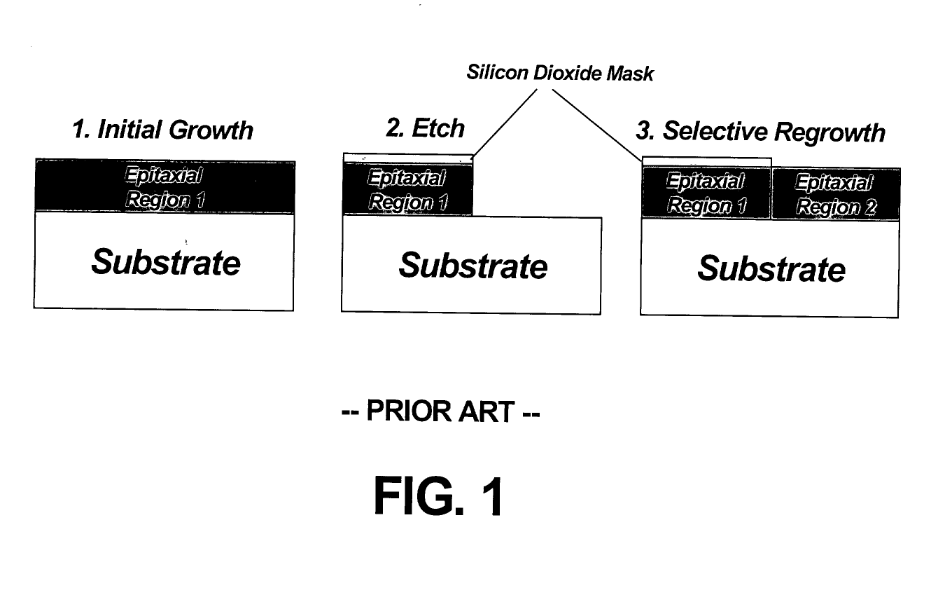

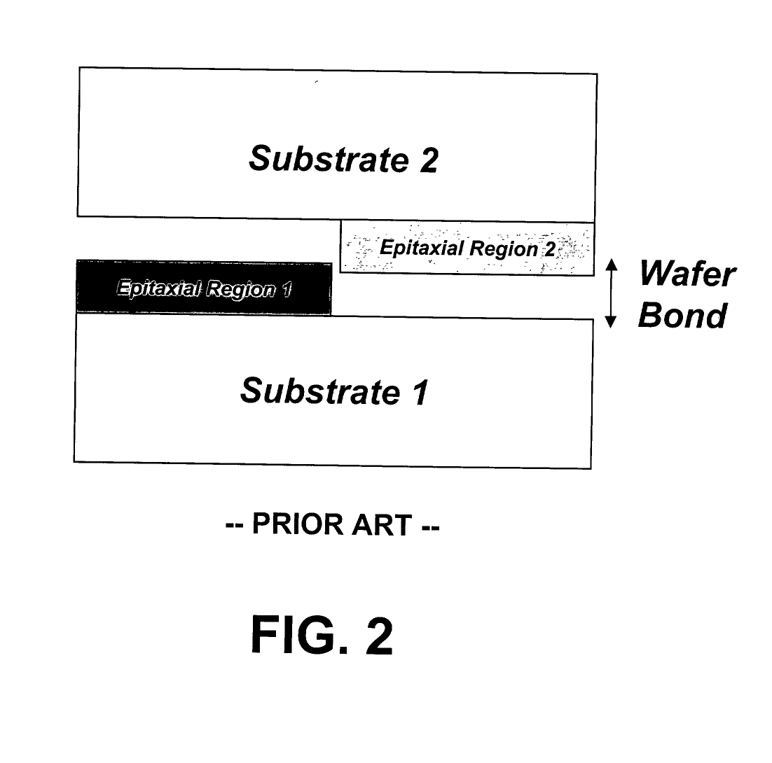

### DETAILED DESCRIPTION OF THE PREFERRED EMBODIMENTS

A substrate having multiple epitaxial regions disposed at different lateral locations and a process of forming such substrate are described. The process involves assembling a plurality of epitaxial layers vertically adjacent to each other on a host substrate to form an epitaxial structure, etching a surface of the epitaxial structure to reveal epitaxial regions of the epitaxial layers at different lateral locations on the host substrate, and wafer bonding the etched surface of the epitaxial structure to a transfer substrate. The host substrate and excess epitaxial layers of the bonded epitaxial structure can be removed to form a final substrate having a plurality of remaining epitaxial regions arranged at different lateral locations thereon and bonded thereto across a single bonded interface.

The bond can be a direct semiconductor-to-semiconductor bond, or may involve intermediate layer(s), such as metal, epoxy, or dielectric films or stack (e.g., dielectric thin films or stack). The transfer substrate may take various forms, as desired, such as a semiconductor, a conductor (e.g., metal), an insulator (e.g., dielectric material such as patterned dielectric film(s) or stack) or combination thereof.

Such a process enables formation of a large number of epitaxial regions on one substrate with excellent epitaxial quality and high yield and which can be employed in various applications discussed in further detail below. Several advantageous embodiments will now be shown and described with reference to the Figures.

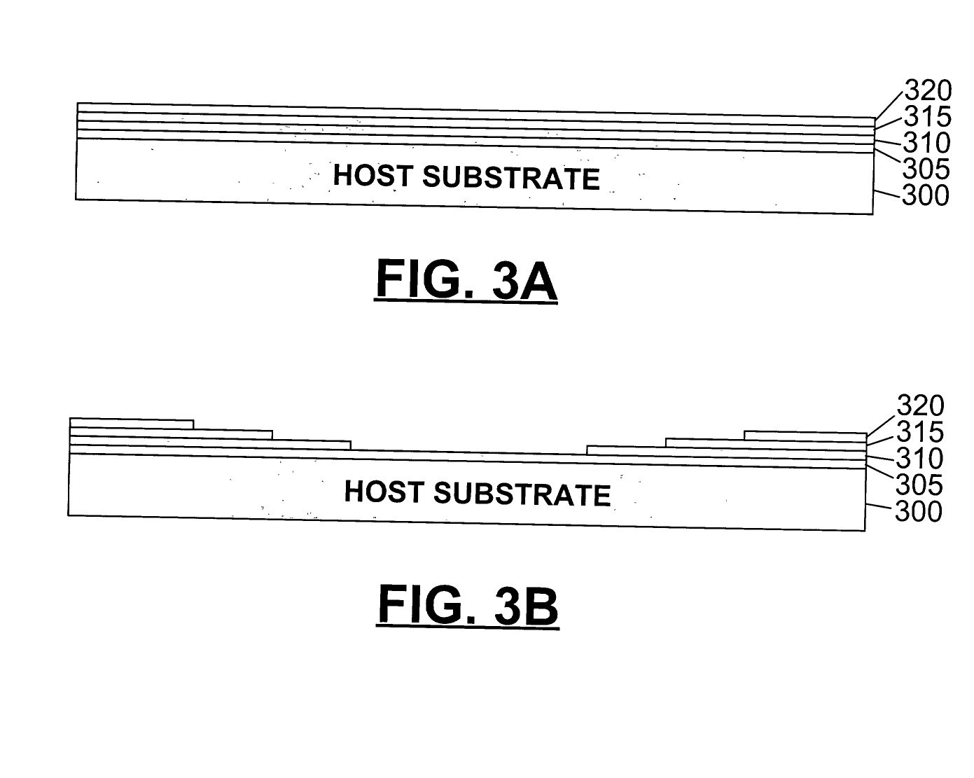

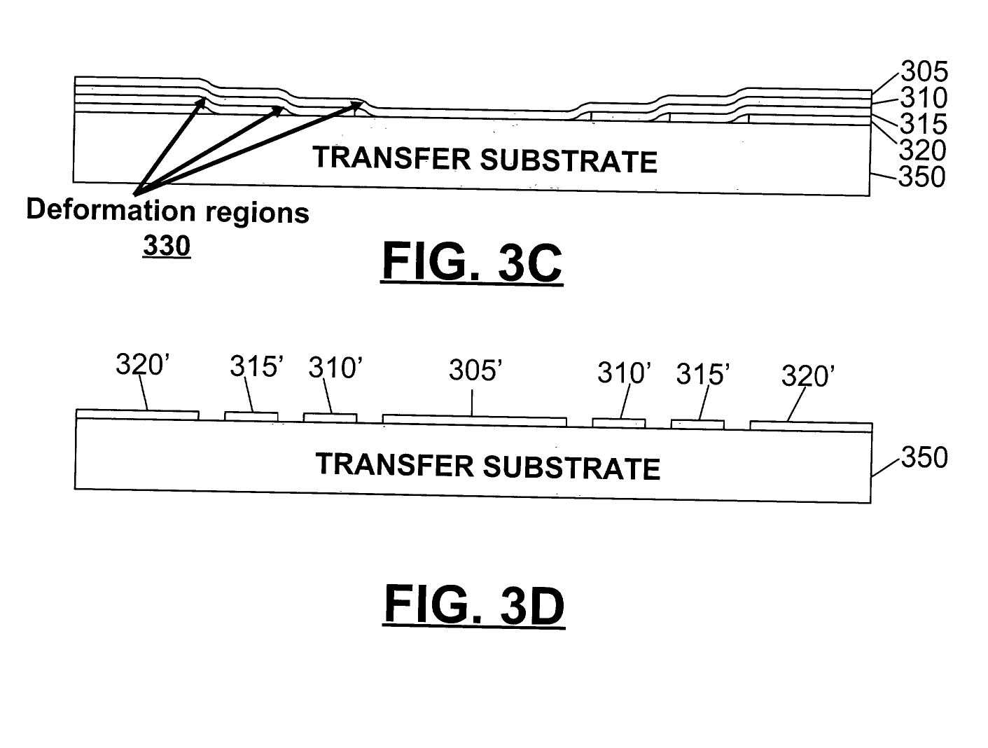

Turning to the drawings, FIGS. 3A through 3D illustrate an exemplary process of forming multiple epitaxial regions on a substrate or final substrate in accordance with one advantageous embodiment. In FIG. 3A, a plurality of epitaxial layers 305, 310, 315 and 320 are integrated vertically by assembling them successively on a host substrate 300 to form an epitaxial structure thereon. In FIG. 3B, the epitaxial structure is then etched different amounts at different lateral locations to reveal or expose epitaxial regions of epitaxial layers 305, 310, 315 and 320 at different lateral locations. As shown, the etched surface of the epitaxial structure has a step profile revealing or exposing a region of each layer at different lateral positions. One or more regions of each layer may be exposed at different lateral locations, as desired.

Thereafter, as shown in FIG. 3C, the exposed non-planar top surface of the epitaxial regions undergoes a single wafer bond to a transfer substrate 350 which may have a different lattice constant than the bonded materials. When pressure is applied during the bonding operation, the non-planar etched surface of the epitaxial structure on host substrate 300 is flattened against transfer substrate 350, causing vertically adjacent regions to become laterally adjacent on the transfer substrate. The vertical to lateral transformation, in this example, involves deformation of regions in the epitaxial structure (e.g., stepped regions between different layers) during bonding which are shown as deformation regions 330. The bonded structure is shown with host substrate 300 removed or omitted therefrom.

The bond can be a direct semiconductor-to-semiconductor bond, or may involve intermediate layer(s), such as metal, epoxy, or dielectric films or stack (e.g., dielectric thin films or stack) to provide adhesion. “Wafer bonding”, as used herein, refers to any technique used to join wafers, regardless of whether an interfacial material is used.

In FIG. 3D, after removal of host substrate 300 and etching of the excess or unwanted epitaxial layers, a plurality of epitaxial regions (e.g., regions 305′, 310′, 315′ and 320′) remain which are laterally adjacent to each other on transfer substrate 350, with some gaps between them where deformation regions 330 have been etched away. The remaining epitaxial regions 305′, 310′, 315′ and 320′ on transfer substrate 350 are attached across a single wafer-bonded interface.

Such a process is distinguishable from the case where aligned wafer bonding is applied multiple times to create multiple epitaxial regions with multiple wafer-bonded interfaces. The single wafer bonded interface can be distinguished from the multiple aligned bond case by a number of features, including:

(1) an exactly replicated crystal alignment between each epitaxial region and the substrate,

(2) consistent bond interface quality from epitaxial region to epitaxial region, and

(3) consistent optical and electrical properties from region to region, since all regions have seen the same single temperature cycle. In the multiple bond scenario, variations in these parameters from region to region would be evident and detectable.

A non-planar wafer bonding approach relying on wafer deformation has previously been described in an article by V. Jayaraman, and M. K. Kilcoyne entitled “WDM Array using long-wavelength vertical cavity lasers,” Proc. SPIE: Wavelength Division Multiplexing Components, 1996, vol. 2690, pp. 325-336, where etching was used to create an array of VCSELs at different wavelengths. There, minor lateral variation in the epitaxial structure was realized by post-growth processing alone. By contrast, the process described herein enables lateral integration of dissimilar or heterogeneous structures, which are non-convertible to each other through post-growth processing alone and do not contain identical epitaxial layers differing only in thickness of the epitaxial layers.

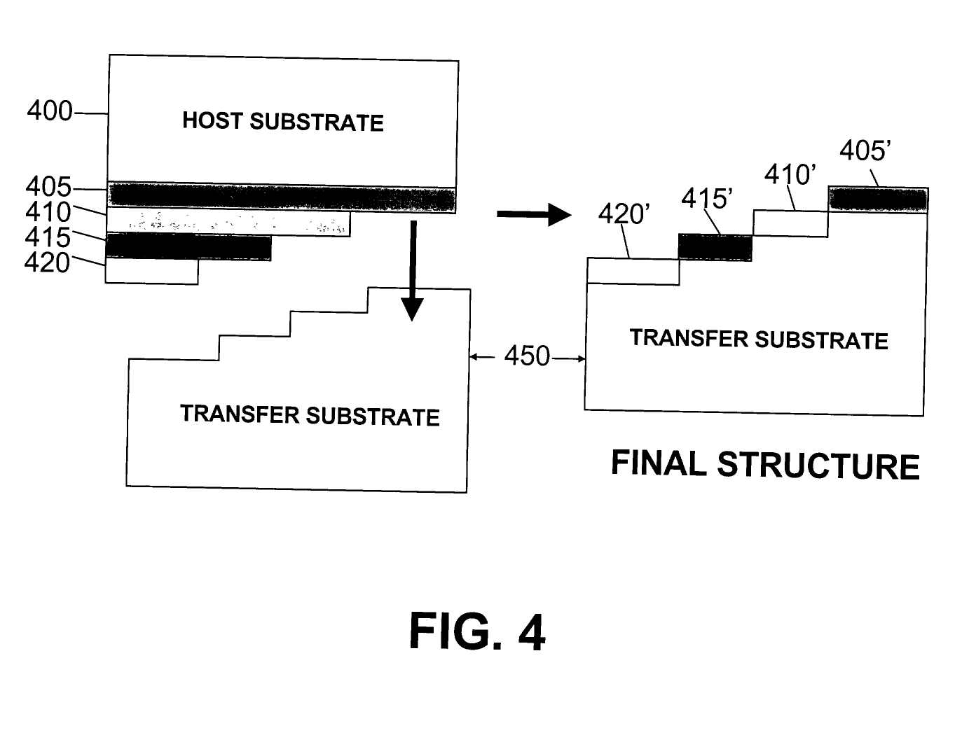

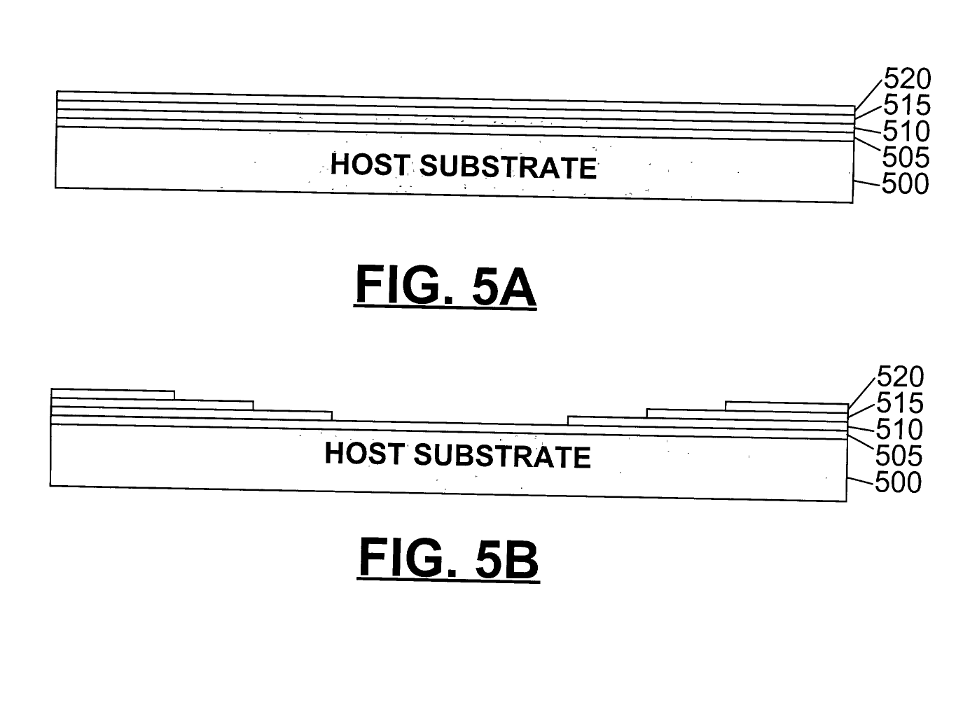

One possible limitation of the technique described herein concerns the amount and distance over which wafers can deform. If step height is too large and step width too small, the wafers may not deform to create a planar surface. An example of a partial solution to this problem is discussed immediately below with reference to FIG. 4.

FIG. 4 illustrates an exemplary process of performing an aligned wafer bond to a transfer substrate with a complementary etch pattern. As shown, after etching the epitaxial layers 405, 410, 415 and 420 (“epitaxial structure”) to reveal or expose various epitaxial regions of the layers on a host substrate 400, an aligned wafer bond is performed to a transfer substrate 450 with a complementary etch pattern. For example, transfer substrate 450 is configured with a bonding surface having a complementary or substantially complementary step pattern to the etched pattern of the epitaxial structure. The bonding surface may be configured to the desired pattern by etching the transfer substrate or depositing materials thereon.

After removal of host substrate 400 and etching of the unwanted or excess epitaxial layers, a final structure or substrate is formed having a plurality of remaining epitaxial regions (e.g., regions 405′, 410′, 415′ and 420′) laterally adjacent to each other on transfer substrate 450 and attached across a single wafer bonded interface.

Such an approach enables integration with arbitrary step height. However, one possible drawback of this technique is that the final structure is not entirely planar. For many applications, however, this is not particularly important. For example, in a laser array application, by a slight tilt, it is still possible to obtain excellent coupling efficiency into an array of optical fibers. One important factor is that the devices are laterally separated on a common substrate, thereby eliminating parasitic conduction paths that exist when structures are vertically integrated. It is also important to note that since wafers will deform somewhat, the step height on the transfer substrate can be smaller than that on the host substrate, leading to a structure that in some cases can be nearly planar if not perfectly planar.

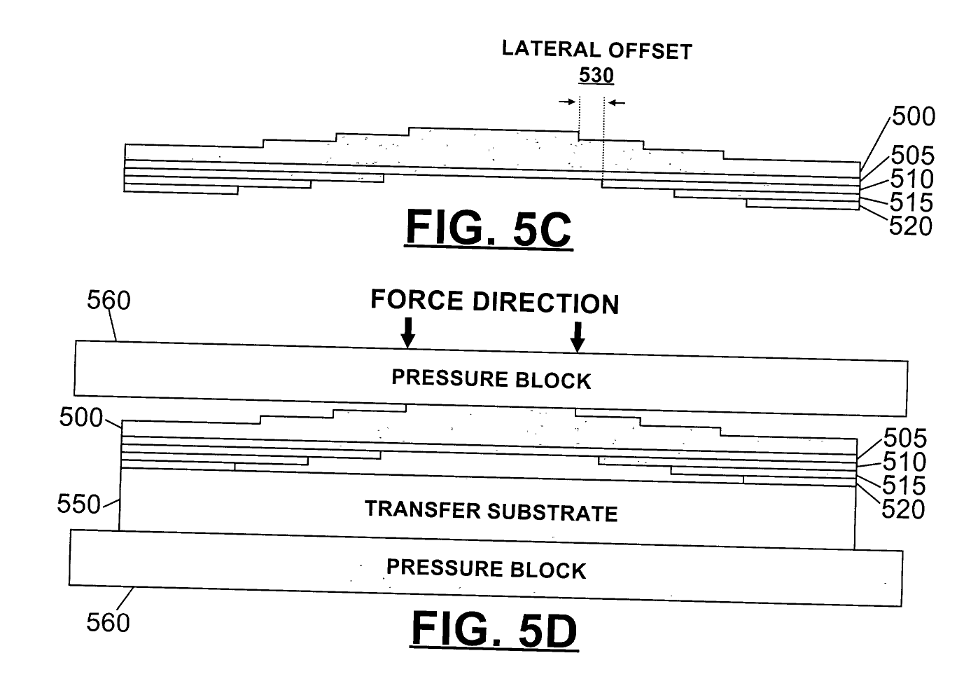

FIGS. 5A through 5D illustrate an exemplary process of performing complementary backside etching or deposition to facilitate non-planar bonding in accordance with another advantageous embodiment. In FIG. 5A, a plurality of epitaxial layers 505, 510, 515 and 520 are integrated vertically by assembling them on a host substrate 500 to form an epitaxial structure on a topside or top surface of the host substrate. In FIG. 5B, epitaxial layers 505, 510, 515 and 520 are etched different amounts at different lateral locations to reveal or expose epitaxial regions of the epitaxial layers at different lateral locations.

In FIG. 5C, host substrate 500 can be configured with a backside having a complementary or substantially complementary shape or pattern to that of the etched surface of the epitaxial structure. The backside pattern of host substrate 500 may be formed by etching. Alternatively, materials can be deposited on the backside of host substrate 500 to form the complementary or near complementary pattern on the backside. Such materials may, for example, include Silicon Nitride, Silicon dioxide, or various metals to create the desired backside pattern.

In either case, the result is that the thickness of the host substrate plus the epitaxial layers plus the deposited material is nearly or approximately constant at each lateral location. Such an arrangement substantially reduces the lateral thickness variation of the host substrate plus the epitaxial layers plus the deposited material.

Furthermore, the backside pattern of host substrate 500 may be configured with lateral offsets 530 to facilitate or accommodate deformation or cleavage (discussed below) at greater step heights during wafer bonding. These lateral offsets may be provided between the step edges of the epitaxial structure side and the step edges of the complementary or substantially complementary shaped backside of the host substrate. The lateral offset determines a distance over which the host substrate and the epitaxial structure must accommodate the deformation. Accordingly, an amount of lateral offset may be increased or decreased according to the step height of the epitaxial structure.

In FIG. 5D, when force is applied to the backside of this wafer via pressure block(s) 560, high spots will be forced downward until the corresponding etched region on the top of the wafer is in contact with transfer substrate 550. Thus, the patterned backside of the wafer promotes the required deformation. While the backside etching or deposition is applied to host substrate 500 in FIGS. 5C and 5D, the backside etching or deposition can be performed on either substrate 500 or 550.

As a result of the applied pressure, the exposed non-planar top surface of the epitaxial structures undergoes a single wafer bond to a transfer substrate 550 with the vertically adjacent epitaxial regions becoming laterally adjacent through deformation. Thereafter, similar to that discussed above with reference to FIG. 3D, host substrate 500 is removed and the unwanted or excess epitaxial layers are etched away to form multiple epitaxial regions laterally adjacent on substrate 550 across a single wafer bonded interface with some gaps where deformation regions have been etched away.

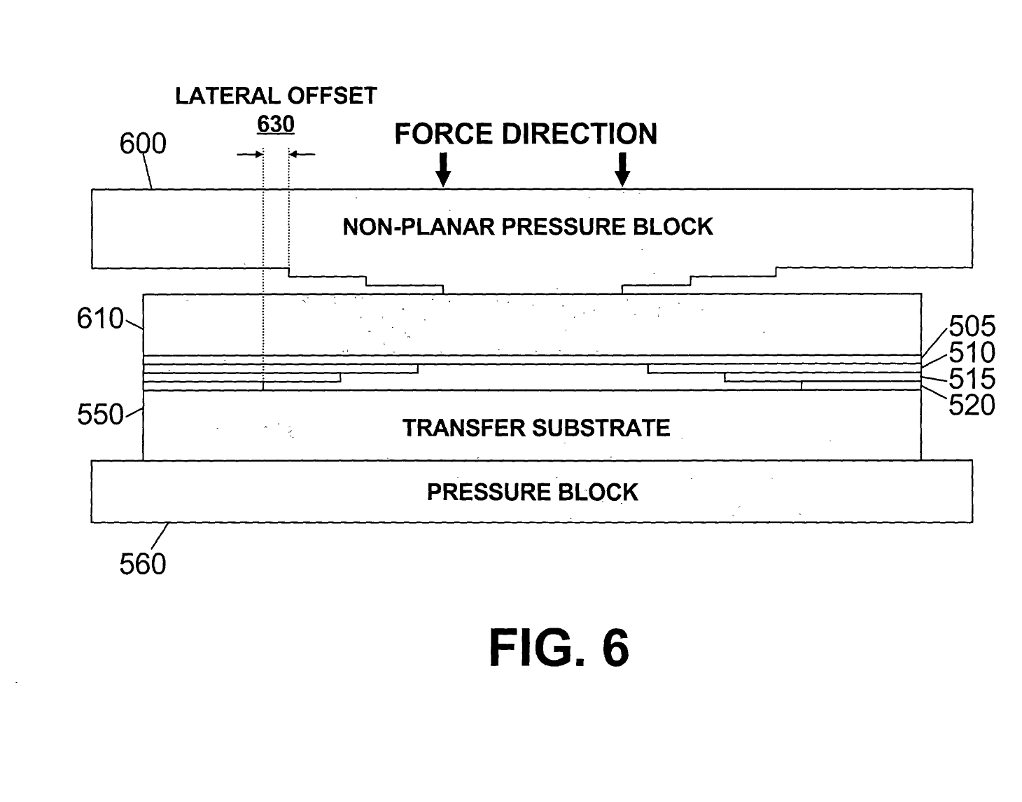

FIG. 6 illustrates another approach to promote the desired deformation by using a non-planar pressure block during wafer bonding in accordance with another advantageous embodiment. Instead of forming a complementary or substantially complementary pattern on a backside of host substrate 500 of FIG. 5D, a pressure block 600 may be configured with a shape that is complementary or substantially complementary to that of the etched epitaxial structure (e.g., layers 505 through 520) on a host substrate 610. The result is that the total thickness of the host substrate plus epitaxial layers plus pressure block is nearly or approximately constant at each lateral position. In this way, lateral thickness variations of the host substrate plus the epitaxial layers plus the pressure block can be reduced.

When pressure block 600 applies force to a backside of host substrate 610, high spots of the etched epitaxial structure on the host substrate will be forced into intimate contact with a surface of transfer substrate 550. While non-planar block 600 is shown as applying force to host substrate 610, the non-planar block can be used instead against transfer substrate 550. For example, pressure block 560 may have a contact surface configured with a complementary or substantially complementary pattern to that of the etched epitaxial structure on the host substrate.

Similar to lateral offset 530 of FIG. 5C, lateral offsets 630 may be provided between the step edges of pressure block 600 and etched epitaxial structure on host substrate 500. Similarly, these lateral offsets 630 facilitate or accommodate deformation or cleavage (discussed below) at greater step heights during wafer bonding, and may be configured accordingly.

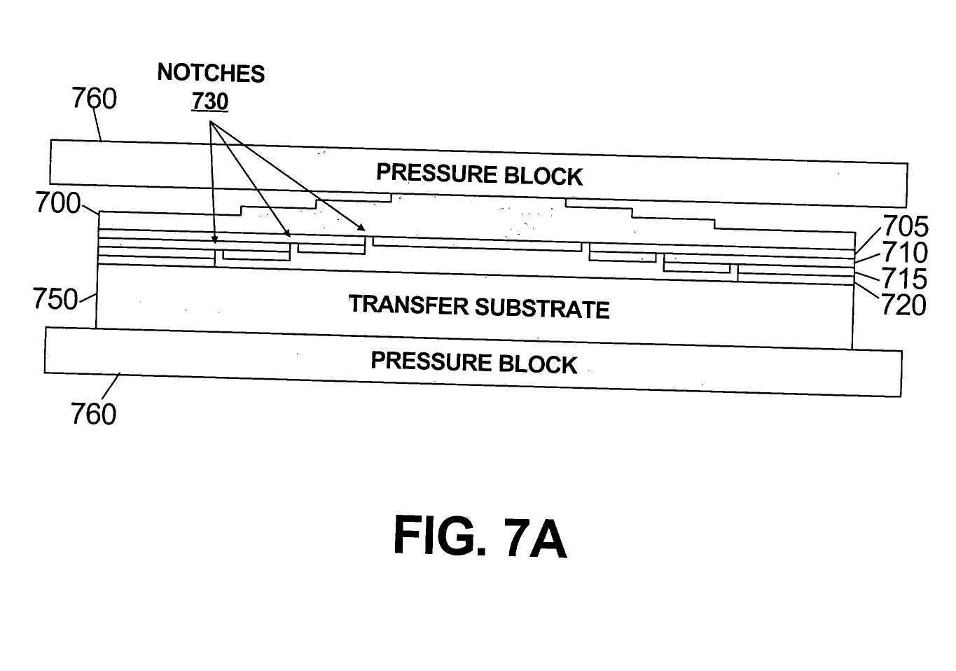

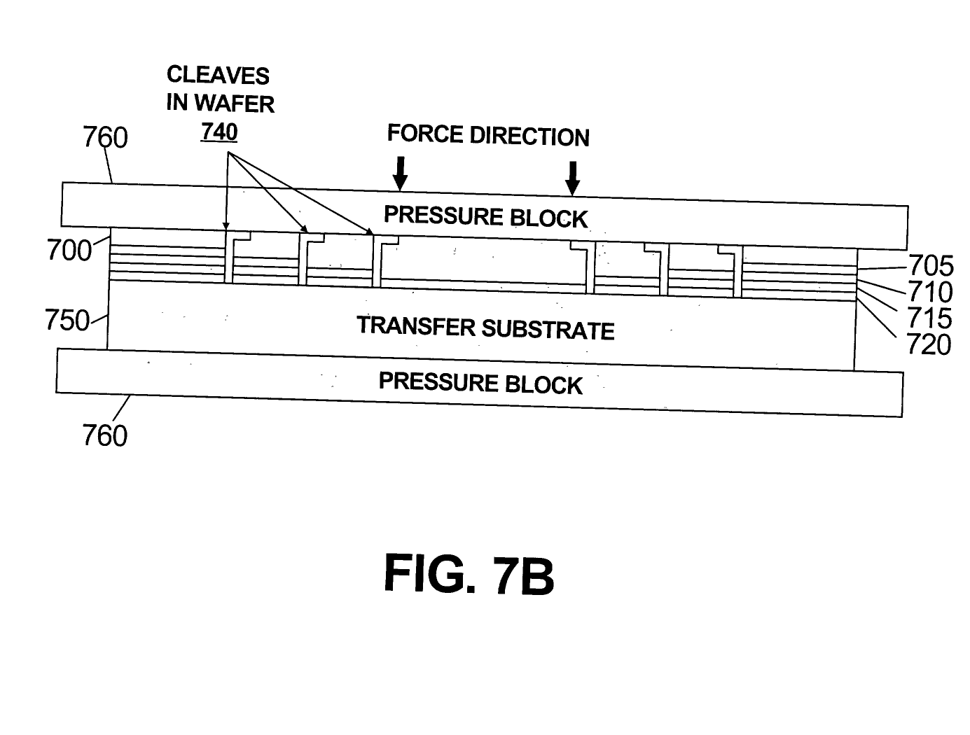

FIGS. 7A and 7B illustrate another approach that can be used to address a potential limitation imposed by the distance and amount wafers can deform. This approach involves causing or facilitating the wafers to cleave along, or near desired locations, such as at step edges or generally between different exposed epitaxial regions during bonding. When complementary backside processing or a non-planar pressure block is used, force is exerted on the wafer to promote bending. This force can be used to cleave the wafer in the direction of the step edge, particularly if the step edge runs along a natural cleavage plane of the wafer. By cleaving the wafer during bonding, much larger step heights can be accommodated. This cleavage can be promoted in many ways, including providing notches in the wafer at locations coinciding with the step edges.

For example, as shown in FIG. 7A, a host substrate 700 includes a front side having an epitaxial structure formed of a plurality of epitaxial layers vertically assembled which are etched to reveal or expose different epitaxial regions of the layers at different lateral locations, and a backside having a shape complementary or substantially complementary to the shape of the epitaxial structure on the front side. Notches 730 may be provided in the epitaxial structure at desired cleavage points prior to application of force via pressure blocks 760 to bond host substrate 700 including the epitaxial structure with transfer substrate 750. For example, notches 730 may be provided at or near step edges of the epitaxial structure and/or host substrate or generally between two different epitaxial regions. The notches may be formed or fabricated in various ways, for example, by scratching or other well-known techniques.

As shown in FIG. 7B, after force is applied by pressure blocks 760, host substrate 700 including the epitaxial structure are bonded to transfer substrate 750. The pressure causes the wafer (e.g., host substrate 700 and the epitaxial structure) to cleave along planes promoted by cleavage points provided by notches 730 as shown by reference numeral 740. Once bonded, the host substrate and excess epitaxial layers may be removed to provide a transfer substrate having a plurality of epitaxial regions at different lateral locations bonded to the transfer substrate across a single bonded interface.

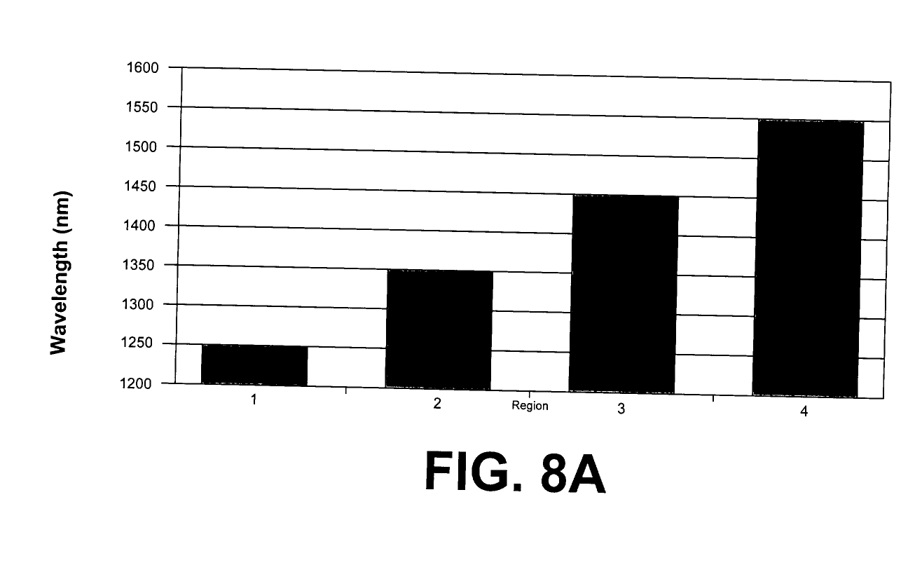

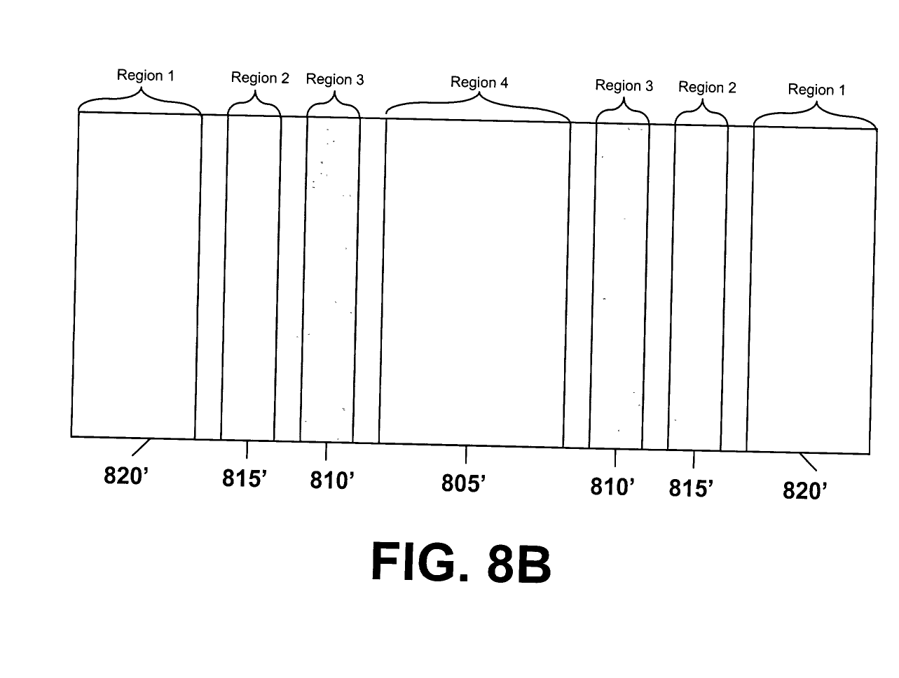

Various examples of the application of the above processes are discussed below with reference to FIGS. 8 through 10. In one advantageous aspect, the non-planar bonding technique may be employed in the integration of different quantum well emission peaks on one substrate, as shown in FIGS. 8A and 8B.

FIG. 8B illustrates a top view of an example of a substrate having a plurality of epitaxial regions thereon at different lateral locations, formed using the non-planar bonding technique discussed herein. The substrate includes a plurality of regions, e.g., regions 1, 2, 3 and 4 identified by respective reference numerals 820′, 815′, 810′ and 805′. Each region has a different quantum well emission peak as shown by reference to the graph of FIG. 8A. In this example, regions 1, 2, 3 and 4 are formed with different quantum well emission peaks optimized for each wavelength 1250 nm, 1350 nm, 1450 nm and 1550 nm, respectively. While FIGS. 8A and 8B show four regions with particular quantum well emission peaks, the non-planar bonding technique may be employed to form any number of regions on a substrate having the desired quantum well emission peaks depending on the desired application.

The non-planar bonding technique may be employed in numerous applications. For example, a wavelength-division-multiplexed (WDM) array of distributed feedback (DFB) lasers can be made on a single substrate, in which each quantum well emission peak is optimized for each wavelength.

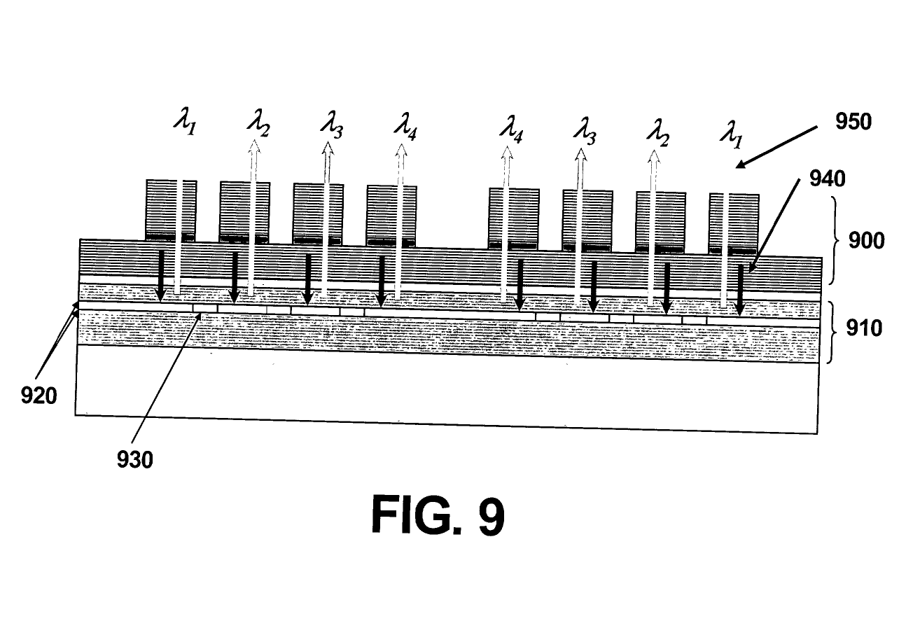

The non-planar bonding technique can be used to form a WDM array of VCSELs that can be either electrically or optically pumped. FIG. 9 shows an example of a WDM VCSEL array using integrated optical pump VCSELs. The structure is formed using wafer-bonded interfaces 920. A top pump laser 900 emits a pump light 940 downward to optically pump the bottom signal laser 910. The signal laser then emits signal light 950 upward. Etched deformation accommodation regions 930 are located between laterally adjacent signal laser devices. WDM DFB/VCSEL arrays today vary the grating pitch or cavity length to vary the wavelength, but are forced to use the same quantum well gain medium for each laser in the array. This limits the array span and compromises the performance of each device in the array. A variant of the DFB array is an array of widely tunable sampled grating Distributed Bragg Reflector (DBR) lasers. The tuning range on these devices is currently limited by the width of the gain spectrum in a specific quantum well structure.

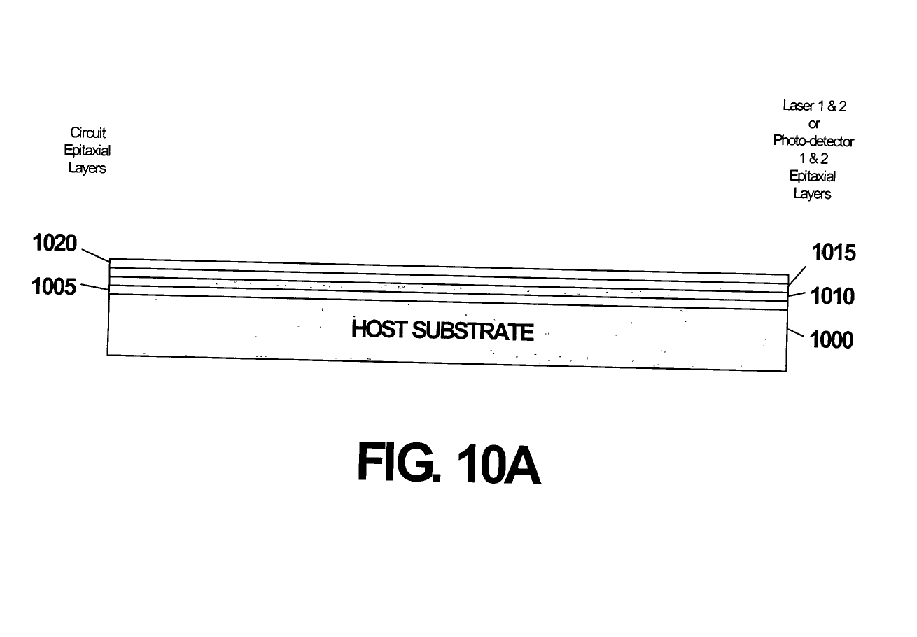

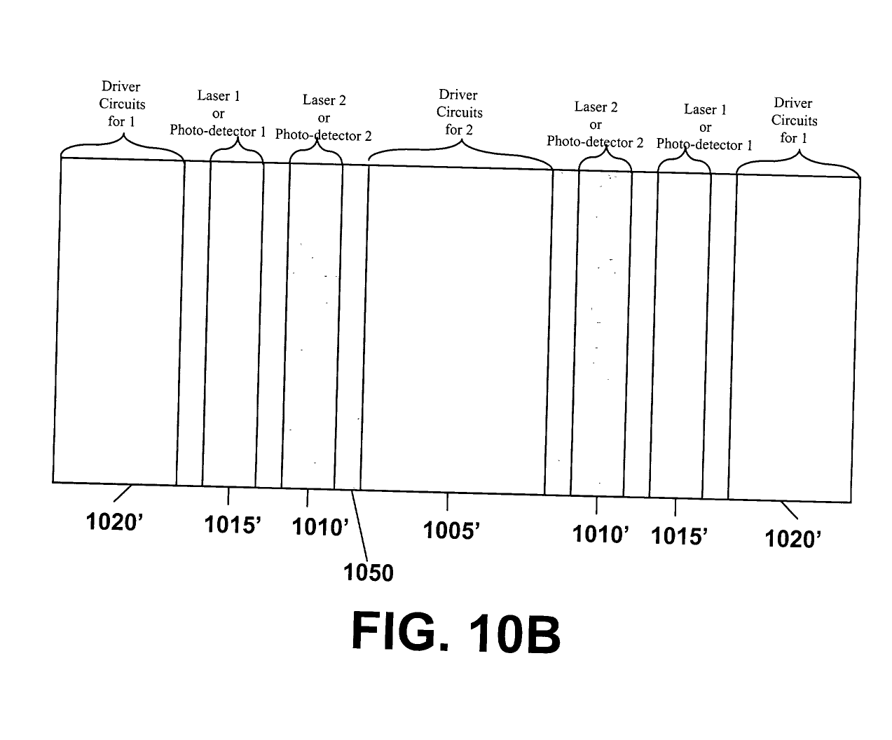

By enabling different lasers in an array to employ different quantum well structures, the effective tuning range can be multiplied by the number of elements in the array. It is also possible to make WDM electro-absorption modulator arrays, where each modulator is optimized for a different wavelength. The non-planar bonding technique herein also allows the integration of epitaxial layers optimized for electronics with epitaxial layers optimized for optical components. This applies to the integration of electronics with optical devices, such as semiconductor lasers or photo-detectors, which is discussed immediately below with reference to FIGS. 10A and 10B.

For example, FIG. 10A illustrates a cross-sectional view of epitaxial layers assembled on a substrate to form a device with integrated electronics or circuits (e.g., drive electronics, etc.) and optical devices or elements or components (e.g., lasers, photodetectors, etc.). As shown, epitaxial layers 1005, 1010, 1015, 1020 may be vertically and successively assembled on a host substrate 1000. In this example, epitaxial layers 1005 and 1020 can be the circuit layers, and epitaxial layers 1010 and 1015 can be the laser or photo-detector layers. This epitaxial structure assembled on host substrate 1000 is etched to reveal or expose epitaxial regions of the layers at different lateral locations and, then, bonded to a transfer substrate 1050 (shown in FIG. 10B). Host substrate 1000 and excess epitaxial layers are removed to form a transfer substrate 1050 with a plurality of epitaxial regions 1005′, 1010′, 1015′ and 1020′ thereon arranged at different lateral locations on transfer substrate 1050 and attached across a single wafer bonded interface, as shown in FIG. 10B.

Epitaxial regions 1010′ and 1015′ may be processed into optical components, such as lasers and/or photo-detectors; and epitaxial regions 1005′ and 1020′ may be processed into driver circuits for such optical components. In this example, epitaxial region 1005′ is processed into the driver circuits for driving the optical components formed from epitaxial regions 1010′; and epitaxial regions 1020′ are processed into the driver circuits for driving the optical components formed from epitaxial regions 1015′.

While the above discusses one example of the different devices which can be integrated on one substrate or on a single chip, the non-planar bonding technique herein may be employed to integrate many different device structures (e.g., optical, micromechanical, electrical, etc.) on one substrate or chip.

The following are examples of structures, devices or components which may be integrated on one substrate or chip:

(1) One or more of each epitaxial region may comprise a laser gain medium and, accordingly, be processed to form a semiconductor laser. The laser gain mediums may have different peak gain wavelengths.

The processed lasers may emit at different wavelengths from each other. The lasers may have the same wavelength offset between their lasing wavelength and their corresponding gain peak wavelength. The laser may be a single-longitudinal-mode in-plane laser, a VCSEL operating in a range of about 1200 nm to about 1650 nm. The VCSEL may include a vertically integrated VCSEL optical pump. The processed laser may also be a tunable laser, which may include at least one sampled grating or may comprise a MEMs tunable VCSEL.

(2) One or more or each epitaxial region may include an absorption region for an electro-absorption modulator and, accordingly, be processed to form an electro-absorption modulator or an array of modulators in a WDM fiber optics transmitter. Each absorption region may have a substantially different absorption band-edge.

The WDM fiber-optic transmitter may include a wavelength-division multiplexed array of lasers; an array of such modulators; and a coupling mechanism to couple the laser array into the modulator array. Each modulator in the array may have a band edge substantially optimized to provide low-chirp modulation for the wavelength of light coupled thereto.

(3) One of the epitaxial regions may be processed into a detector for detecting optical radiation, and another of the epitaxial regions may be processed into an amplifier circuit for amplifying the photocurrent generated by the detector.

(4) One of the epitaxial regions may be processed into a laser, and another epitaxial region may be processed into a circuit for applying electrical drive to the laser.

(5) One of the epitaxial regions may be processed into a laser and another epitaxial region may be processed into a modulator that modulates at least one of an amplitude and phase of light emitted by the laser.

(6) One of the epitaxial regions may be processed into a laser, and another of the epitaxial regions may be processed into a detector for detecting optical radiation.

(7) One of the epitaxial regions may be processed into an optical, micromechanical or electronic device, and another epitaxial region may be processed into a drive circuit for such the device.

(8) Two different epitaxial regions may be processed to form two different devices.

The above are a few examples of the various components, elements or devices which may be integrated onto one substrate or chip.

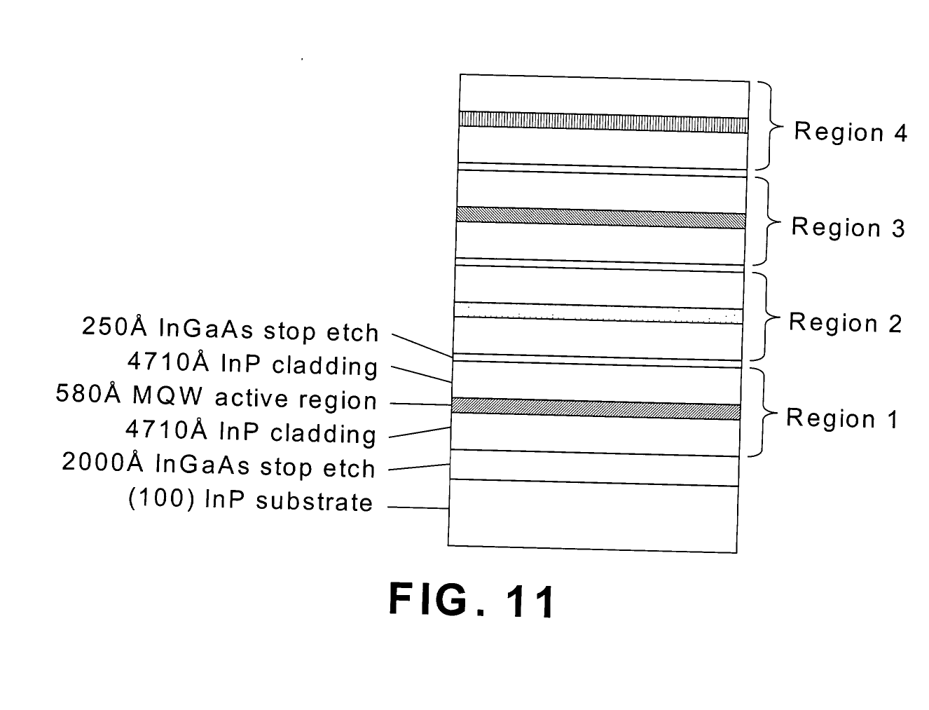

A test example using various embodiments of the non-planar wafer bonding technique herein is discussed below with reference to FIGS. 11 through 15.

### EXAMPLE

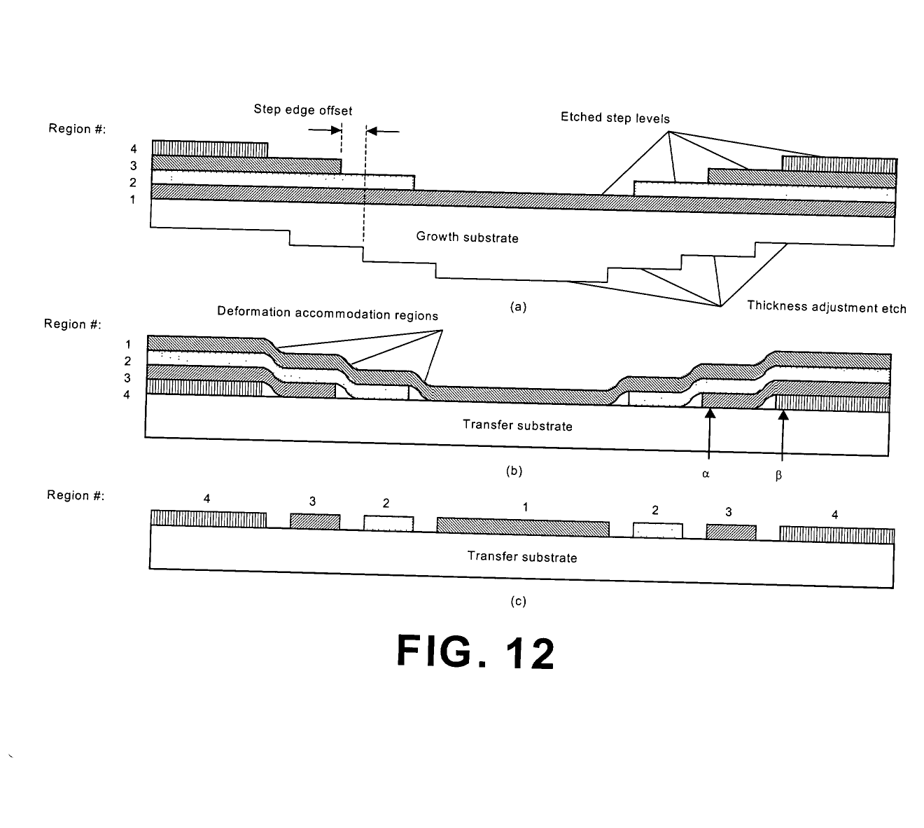

To test the non-planar wafer bonding technique, four different unstrained multi-quantum-well (MQW) active-regions were grown on (100 orientation) Indium Phosphide (InP) by chemical vapor deposition (CVD) such as Metal/Metello Organic Chemical Vapor Deposition (MOCVD) as shown by reference to FIGS. 11 and 12. The MQW active-regions included three 60 Å InGaAsP quaternary (Q) quantum wells with 100 Å 1.1 μm Q barriers. Each of the four regions were separated by a 250 Å InGaAs stop etch layer for ease of processing and substrate removal. The photoluminescence (PL) peaks of the four regions were intentionally made different to ultimately achieve different PL peaks at laterally adjacent regions on the wafer. The regions had MQW PL peaks at 1280, 1336, 1260, and 1320 nm, listed in order of their growth on the substrate. Each region had a thickness of 1.025 μm, for a total epitaxial film thickness of about 4.1 μm.

The epitaxial layers were selectively chemical etched with a step profile to reveal a different region on each step level. The step levels were 500 μm wide and 1.025 μm high. The 1 cm² substrate was thinned to 200μm and the backside was chemically etched with the same step profile as the epitaxial film side, except with a 200 μm lateral step edge offset. The photoluminescence of the wafer was measured at each step level prior to the direct wafer bonding of the epitaxial layers to a (100 orientation) GaAs substrate. The semiconductor direct wafer bond was performed at 630° C. for 30 minutes in a nitrogen gas ambient under pressure in a graphite fixture. The pressure applied was in the same range used in the planar bonding of InP to GaAs (3 MPa) in the fabrication of 1.55 μm vertical-cavity surface emitting lasers (VCSELs).

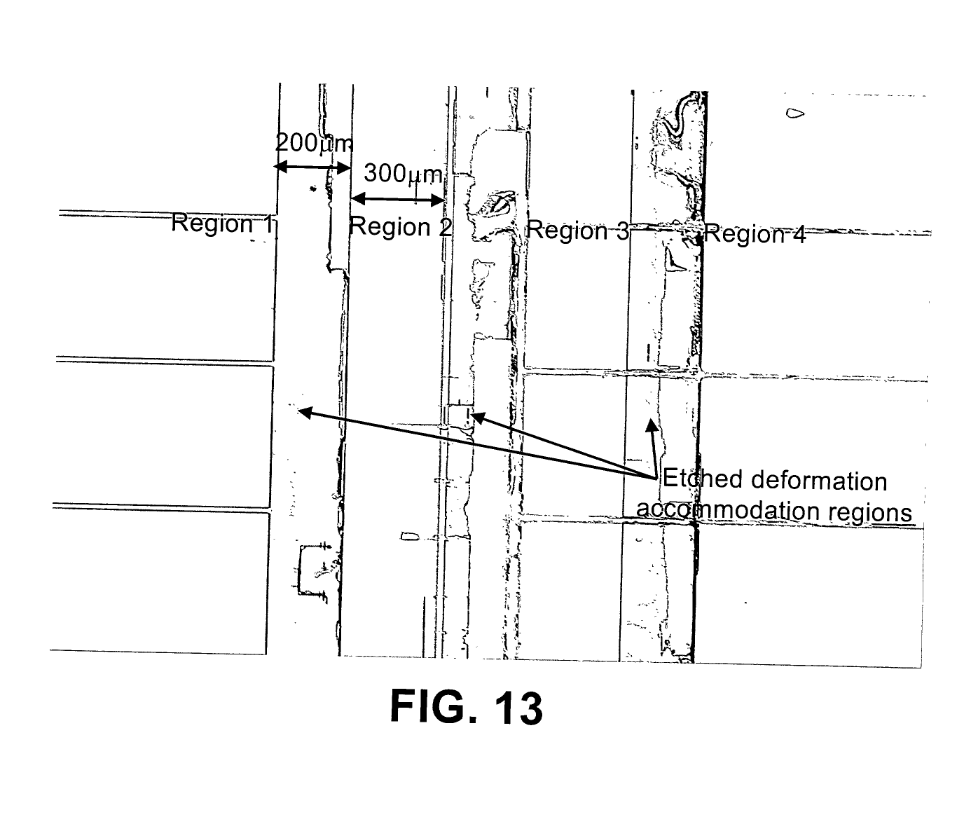

After direct bonding the InP to the GaAs transfer substrate, the InP substrate was removed by a selective chemical etching. The excess epitaxial layers and the deformation accommodation regions were etched back by selective chemical etching to reveal well-fused stripes of MQW active regions across the GaAs transfer substrate surface. FIG. 13 shows the stripes of epitaxial regions separated by the etched deformation accommodation regions. The roughness of the deformation accommodation regions is due to the uneven etching of the GaAs transfer substrate during the etch-back process.

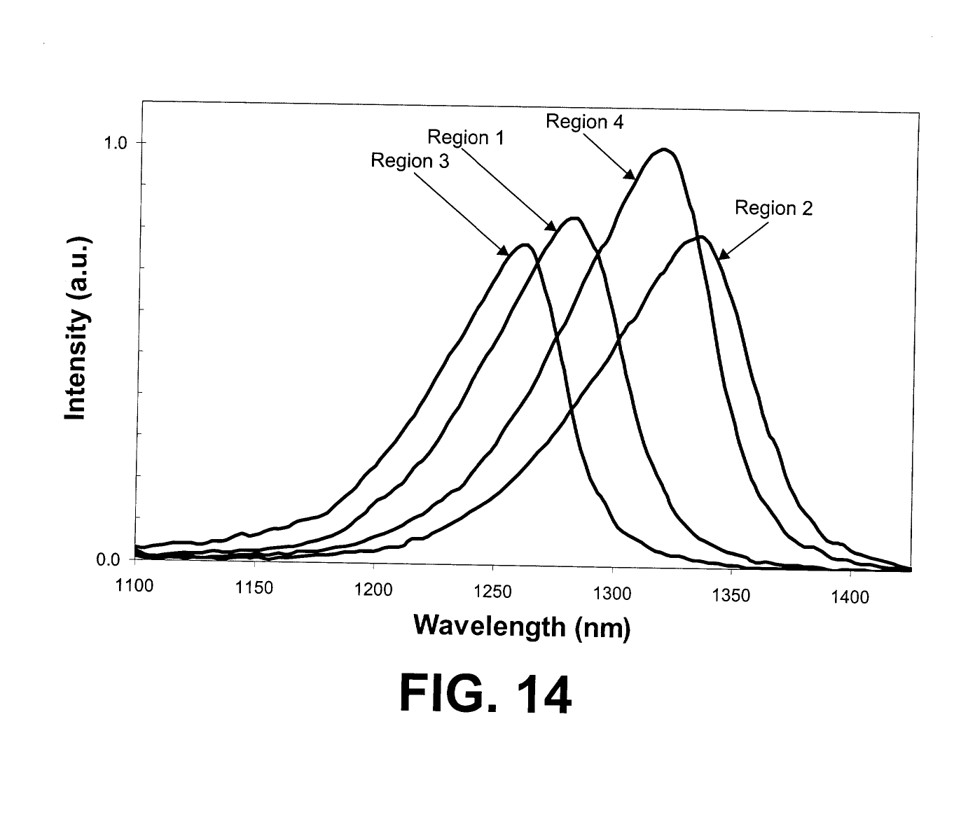

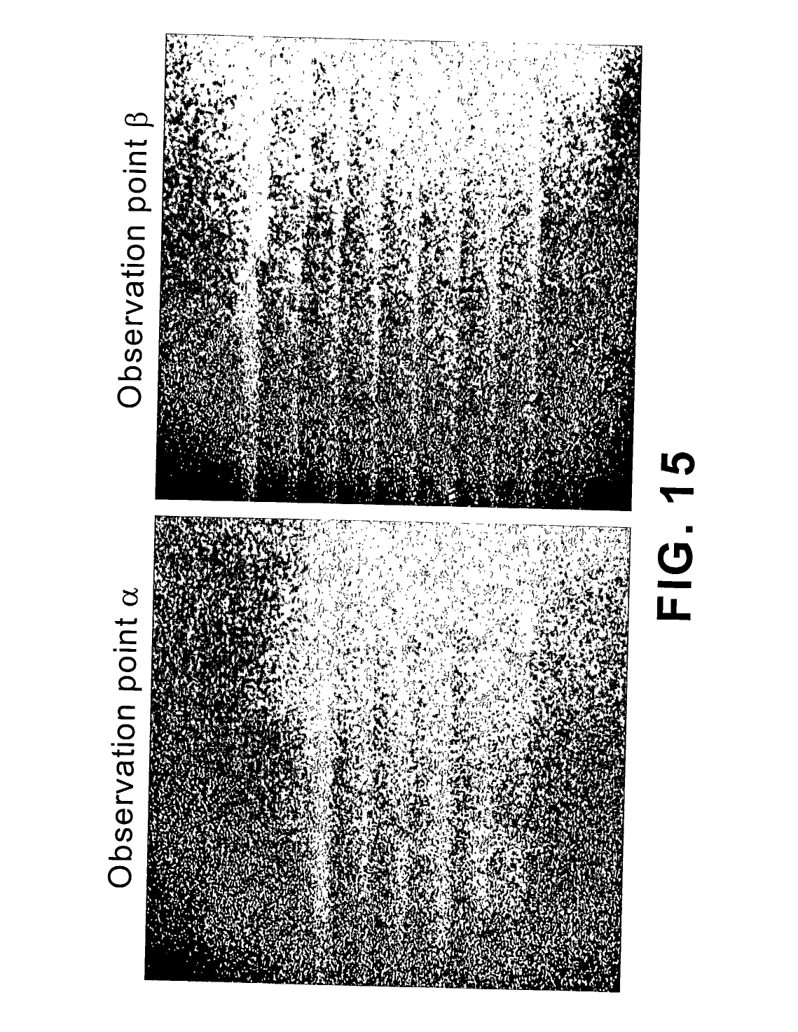

PL measurements taken after wafer bonding are shown in FIG. 14. The PL prior to wafer bonding is not shown, but comparison with the PL plots in FIG. 14 indicates no degradation in the intensity, no shift in the wavelength, and no broadening of the PL peaks after wafer bonding. Optical inspection of the surface shows a well-bonded surface with very little damage due to bonding. Scanning electron microscope (SEM) images of the bonded interface also reveal a uniform wafer bonded interface. FIG. 15 illustrates cross-section SEM images of the sample at two observation points labeled α and β in the schematic diagram of FIG. 12b. These images where taken prior to the InP substrate removal step.

The combination of good PL and a mechanically well-bonded surface provides support for the conclusion that the non-planar wafer bonding technique may be employed to achieve vertical and lateral heterogeneous integration across a wafer. This technique may be used for the monolithic integration of various optical, electrical, and micromechanical components on a single wafer. This technique allows epitaxial regions, optimized for specific applications, to be integrated onto a single planar wafer in a single step.

Examples of specific applications may include WDM laser arrays (as discussed above) and the integration of electronics with lasers, photodetectors, and modulators. This technique may also allow an increase in the level of integration in photonic integrated circuits by enabling many different kinds of devices to be combined on a single semiconductor chip. Coupling between areas can be accomplished by three dimensional photonic integration techniques, or by other waveguide deposition techniques.

The non-planar wafer bonding approach, as discussed herein, may be employed to achieve vertical and lateral heterogeneous integration on a wafer. SEM and optical inspection have confirmed the good bond quality of the direct non-planar wafer bond. Photoluminescence after wafer bonding confirms that the optical properties of the MQW active-regions were maintained after the bonding process. This technique can be used to integrate many different device structures on a single chip and may represent an advance in the level of complexity of optical, electronic, and micromechanical integration possible.

The many features and advantages of the present invention are apparent from the detailed specification, and thus, it is intended by the appended claims to cover all such features and advantages of the invention which fall within the true scope of the present invention.

Furthermore, since numerous modifications and variations will readily occur to those skilled in the art, it is not desired that the present invention be limited to the exact construction and operation illustrated and described herein, and accordingly, all suitable modifications and equivalents which may be resorted to are intended to fall within the scope of the claims.

What is claimed is:

1. A method of forming a semiconductor substrate having a plurality of epitaxial regions disposed at different lateral locations, the method comprising:
assembling a plurality of epitaxial layers vertically adjacent to each other on a host substrate to form an epitaxial structure;
etching a surface of the epitaxial structure to reveal epitaxial regions of the epitaxial layers at different lateral locations on the host substrate; and
wafer bonding the etched surface of the epitaxial structure to a transfer substrate.

2. The method of claim 1, further comprising etching a backside of the host substrate, opposite the epitaxial structure, to reduce lateral thickness variation of the host substrate plus the epitaxial layers, prior to wafer bonding.

3. The method of claim 1, further comprising etching a backside of the transfer substrate, opposite a bonding side, to reduce the lateral thickness variation of the transfer substrate plus the epitaxial layers plus the host substrate, prior to wafer bonding.

4. The method of claim 1, further comprising depositing material on a backside of the host substrate, opposite the epitaxial layers, to reduce lateral thickness variation of the host substrate plus the deposited material plus the epitaxial layers, prior to wafer bonding.

5. The method of claim 1, further comprising depositing material on a backside of the transfer substrate to be bonded to reduce the lateral thickness variation of the transfer substrate plus the host substrate plus the deposited material plus the epitaxial layers, prior to wafer bonding.

6. The method of claim 1, further comprising:
etching a surface of the transfer substrate to form a bonding surface having a complementary shape to the etched surface of the epitaxial structure on the host substrate; and
aligning the host substrate and the transfer substrate, prior to wafer bonding, to reduce the lateral thickness variation of the host substrate plus the epitaxial layers plus the transfer substrate.

7. The method of claim 1, wherein the wafer bonding comprises applying pressure with at least one pressure block having a surface for pressure application which has a shape that substantially reduces the lateral thickness variation of the pressure block plus the host substrate plus the epitaxial layers plus the transfer substrate.

8. The method of claim 1, further comprising:
removing the host substrate and excess epitaxial layers of the bonded epitaxial structure to form a final substrate having a plurality of remaining epitaxial regions arranged at different lateral locations thereon and bonded thereto across a single bonded interface.

9. The method of claim 8, wherein the wafer bonding forms deformation regions between revealed epitaxial regions of the epitaxial structure bonded to the transfer substrate, the method further comprising removing the deformation regions.

10. The method of claim 1, further comprising providing notches at cleavage points on the etched epitaxial structure to promote cleavage along planes intersecting the notches when the epitaxial structure is bonded to the transfer substrate.

11. The method of claim 10, wherein the notches are provided on the epitaxial structure at positions between revealed epitaxial regions.

12. The method of claim 10, wherein the notches are formed by scratching.

13. The method of claim 8, further comprising processing at least one of the remaining epitaxial regions of the final substrate to form one of an optical, micromechanical and electronic device and another of the remaining epitaxial regions to form a drive circuit for the form one of an optical, micromechanical and electronic device.

14. The method of claim 13, wherein the optical device comprises one of a laser and photo-detector.

15. The method of claim 8, further comprising processing two different epitaxial regions of the final substrate to form two different devices therefrom.

16. The method of claim 1, wherein the etched surface of the epitaxial structure is directly bonded to the transfer substrate.

17. The method of claim 1, wherein the etched surface of the epitaxial structure is bonded to the transfer substrate across one or more intermediate layers.

18. The method of claim 17, wherein the one or more intermediate layers include a metal.

19. The method of claim 17, wherein the one or more intermediate layers include an epoxy.

20. The method of claim 17, wherein the one or more intermediate layers include dielectric films.

21. The method of claim 20, wherein the dielectric films comprises dielectric thin films.

22. The method of claim 1, wherein the transfer substrate comprises a patterned dielectric stack.

23. A method of forming a semiconductor substrate having a plurality of epitaxial regions disposed at different lateral locations, the method comprising:
forming an epitaxial structure on a host substrate, the epitaxial structure having a surface in which at least two different epitaxial regions of different epitaxial layers are exposed and arranged at different lateral and vertical locations on the host substrate; and
wafer bonding the surface of the epitaxial structure to a transfer substrate;
removing the host substrate and excess epitaxial layers to form a substrate having at least two different epitaxial regions thereon at different lateral locations and connected across a single wafer bonded interface.

24. A semiconductor structure comprising:
a substrate;
at least two epitaxial regions laterally disposed on the substrate, each of the epitaxial regions non-convertible to any of the other epitaxial regions through post-growth processing alone, and formed from different epitaxial layers; and
a single common wafer bonded interface between each of the epitaxial regions and the substrate.

25. The structure of claim 24, wherein each epitaxial region comprises a laser gain medium.

26. The structure of claim 25, wherein each gain medium has a different peak gain wavelength.

27. The structure of claim 25, wherein a semiconductor laser is processed on each epitaxial region.

28. The structure of claim 27, wherein each semiconductor laser emits at a different wavelength.

29. The structure of claim 28, wherein each semiconductor laser has the same wavelength offset between its lasing wavelength and its corresponding gain peak wavelength.

30. The structure of claim 28 wherein each laser is a single-longitudinal-mode in-plane laser.

31. The structure of claim 28, wherein each laser is a VCSEL.

32. The structure of claim 31, wherein each VCSEL operates in the range of approximately 1200 nm to approximately 1650 nm.

33. The structure of claim 32, wherein each VCSEL includes a vertically integrated VCSEL optical pump.

34. The structure of claim 27, wherein each laser comprises a tunable laser.

35. The structure of claim 34, wherein each tunable laser includes at least one sampled grating.

36. The structure of claim 34, wherein each tunable laser comprises a MEMs tunable VCSEL.

37. The structure of claim 24, wherein each epitaxial region includes an absorption region for an electro-absorption modulator.

38. The structure of claim 37, wherein each absorption region has a substantially different absorption band-edge.

39. The structure of claim 37, wherein an electro-absorption modulator is processed on each epitaxial region.

40. The structure of claim 24, wherein one of the regions is optically active and another of the regions is optically passive.

41. The structure of claim 24, wherein one of the regions is processed into a detector for detecting optical radiation, and another is processed into an amplifier circuit for amplifying the photocurrent generated by the detector.

42. The structure of claim 24, wherein one of the regions is processed into a laser, and another region is processed into a circuit for applying electrical drive to the laser.

43. The structure of claim 24, wherein one of the regions is processed into a laser and another into a modulator that modulates at least one of an amplitude and phase of light emitted by the laser.

44. The structure of claim 24, wherein one of the regions is processed into a laser, and another of the regions is processed into a detector for detecting optical radiation.

45. The structure of claim 24, wherein the bonded interface includes one or more intermediate layers.

46. The structure of claim 45, wherein the one or more intermediate layers include a metal.

47. The structure of claim 45, wherein the one or more intermediate layers include an epoxy.

48. The structure of claim 45, wherein the one or more intermediate layers include dielectric films.

49. The structure of claim 48, wherein the dielectric films comprises dielectric thin films.

50. The structure of claim 24, wherein the substrate comprises a patterned dielectric stack.

51. A wavelength-division multiplexed fiber optic transmitter comprising:
a wavelength-division multiplexed array of lasers; and
an electro-absorption modulator array, coupled to the laser array, comprising a semiconductor structure including:
a substrate,
at least two epitaxial regions laterally disposed on the substrate, each of the epitaxial regions non-convertible to any of the other epitaxial regions through post-growth processing alone, and formed from different epitaxial layers, and
a single common wafer bonded interface between each of the epitaxial regions and the substrate,
wherein each epitaxial region includes an absorption region for an electroabsorption modulator and an electro-absorption modulator is processed on each epitaxial region.

52. The transmitter of claim 51, wherein each modulator in the array has a band edge substantially optimized to provide low-chirp modulation for the wavelength of light coupled thereto.

53. A wavelength-division multiplexed fiber optic transmitter comprising:
an electro-absorption modulator array, coupled to a wavelength-division multiplexed array of lasers, wherein the laser array comprises a semiconductor structure including:
a substrate,
at least two epitaxial regions laterally disposed on the substrate, each of the epitaxial regions non-convertible to any of the other epitaxial regions through post-growth processing alone, and formed from different epitaxial layers, and
a single common wafer bonded interface between each of the epitaxial regions and the substrate,
wherein each epitaxial region includes a gain region for a laser-and a laser is processed on each epitaxial region.

54. The transmitter of claim 53, wherein each laser in the array has the same wavelength offset between its lasing wavelength and its corresponding gain peak wavelength.
